(19) United States
(12) Patent Application Publication
(10) Pub. No.: US 2006/0279811 A1
(43) Pub. Date: Dec. 14, 2006

(54) Method for adjusting colors of image

(76) Inventors: Shiang-Tan Lin, Keelung City (TW); Yu-Ju Lee, Sijhih City (TW)

Correspondence Address: J C PATENTS, INC., 4 VENTURE, SUITE 250, IRVINE, CA, 92618, US

(21) Appl. No.: 11/158,411

(22) Filed: Jun. 21, 2005

(30) Foreign Application Priority Data
Jun. 9, 2005 (TW) 94119006

(51) Int. Cl. G03F 3/08

(52) U.S. Cl. 358/518; 358/538

(57) ABSTRACT

A method for adjusting color images is disclosed, which adjusts color signals within predetermined adjust regions without conversion of color model. The adjust effects are gradual and the possibility of occurrence of error profiles is low. The adjust regions are defined and selected. It is judged whether color signals of color images are located within the adjust region. If color signals of color images are located within the adjust region, an adjust factor is defined on the basis of a distance between the color signal and boundaries of the adjust region. Red (R), green (G) and blue (B) gray scales of the color signal are adjusted based on the adjust factor, without conversion of color model.

### CROSS-REFERENCE TO RELATED APPLICATION

This application claims the priority benefit of Taiwan application serial no. 94119006, filed on Jun. 9, 2005. All disclosure of the Taiwan application is incorporated herein by reference.

### BACKGROUND OF THE INVENTION

1. Field of Invention

The present invention relates to a method for adjusting color images. More particularly, the present invention relates to a method for adjusting color images in a predetermined region.

2. Description of Related Art

In the case of displaying the color image on television sets, R (red), G (green) and B (blue) signals of color images are converted into luminance signals Y and two color difference signals R-Y and B-Y, which represent the hue and saturation of color images. In prior art, the hue signals, saturation signals and luminance signals are adjusted under (Y, R-Y and B-Y) color model.

However, there are two drawbacks in the prior art. First, the whole gray scales of color signals are adjusted simultaneously, and it is difficult to adjust one arbitrary color. For example, it's difficult to enhance color saturation of blue sky, white cloud, or red sunset images in a predetermined region, or to adjust distorted skin colors. Second, even in the case of inputting digital RGB signals, the digital RGB signals are converted into the Y, R-Y and B-Y signals of the Y, R-Y and B-Y color model, and then, those signals are again converted into R, G and B signals and output. This conversion process increases complexity and cost of adjusting circuits.

U.S. Pat. No. 5,060,060 discloses another method and apparatus for processing color images. In U.S. Pat. No. 5,060,060, R, G and B signals are converted into the Y, R-Y and B-Y signals, and then, the Y, R-Y and B-Y signals are converted into the luminance (Y′), hue (H) and saturation (C) signals. If technical features of U.S. Pat. No. 5,060,060 are applied in the color display in television sets, the luminance (Y), hue (H) and saturation (C) signals are converted into the R, G and B signals.

U.S. Pat. No. 5,585,860 discloses still another reproduction circuit for skin colors in the Y, R-Y and B-Y model. In U.S. Pat. No. 5,585,860, color signals are converted between the RGB model and the Y, R-Y and B-Y model.

There is a need to adjust color images in predetermined region in the RGB model without conversion of color models.

### SUMMARY OF THE INVENTION

One aspect of the invention is to provide an adjusting method for color images, adjusting color signals in predetermined regions under RGB color model without conversion of color model. The complexity and cost of apparatus applying the invention is low.

Another aspect of the invention is to provide a method for adjusting color images in predetermined adjust region under appropriate suitable color model. In the adjust method, adjusting effects of the color signals locating on or close to the boundary lines of the adjust regions are small, but adjust effects of color signals far away from the boundary lines are significant. So the adjust effects are gradual, and possibility of preventing occurrence of false contour is low.

To at least achieve the above and other aspects, the invention provides a method for adjusting color images. In this method, an adjust region is defined and selected. It is judged whether color signals of the color image are within the adjust region. Red (R), green (G) and blue (B) gray scales of the color signals are adjusted without conversion of color model, if the color signals are within the adjust region.

In one embodiment, the adjusting step includes the steps of: defining an adjust factor based on a distance between the color signals and boundaries of the adjust region; and adjusting red, green and blue gray scales of the color signals based on values of the adjust factor.

In one embodiment, the boundaries of the adjust regions are defined by one or more inequalities including R, G and B gray scales of color signals.

In one embodiment, the adjust factor is a product of a plurality of boundary factors, each corresponding to one of the inequalities.

In one embodiment, the boundary factor is an ascending function of the distance between the color signals and boundaries defined by the corresponding inequalities. The boundary factor is 0 if the color signals located on the corresponding boundary. An upper limit of the boundary factor is 1.

In one embodiment, the step of adjusting the color signals based on values of the adjust factor further includes the steps of performing an addition or multiplication operation on corresponding gains and red, green and blue gray scales of the color signals, wherein the gains are determined based on the adjust factor.

Still other aspect of the invention is to provide a method for adjusting color images, the method including the steps of: defining and selecting an adjust region; judging whether a color signal of the color image is located within the adjust region; defining an adjust factor on the basis of a distance between the color signal and boundaries of the adjust region, if the color signal is located within the adjust region; and adjusting the color signal based on values of the adjust factor without conversion of color model.

As above, the adjusting method for color images according to the present invention adjusts color signals in predetermined regions under RGB color model, without conversion of color model. The complexity and cost of apparatus applying the invention is low.

In the adjust method, the color images locating within predetermined adjust regions are adjusted based on the adjust factor, which is an ascending function of the distance between the color signals and the boundaries of the adjust regions. If the color signals locate on or close to the boundary lines of the adjust regions, the adjust factor are 0 or small, which means the adjust effects of color signals locating on or close to the boundary lines are small. On the other hand, the adjust effects of color signals far away from the boundary lines are significant. So the adjust effects are gradual for preventing occurrence of error profiles.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a chromaticity diagram applied in one preferred embodiment of the present invention.

FIG. 2 and FIG. 3 are schematic views in adjusting the R gray scale in color signals according to the preferred embodiment of the present invention.

FIG. 4 shows the flow chart of the color images adjusting method according to the preferred embodiment of the present invention.

### DESCRIPTION OF THE PREFERRED EMBODIMENTS

Reference will now be made in detail to the present preferred embodiments of the invention, examples of which are illustrated in the accompanying drawings.

A color image is constituted of color signals of a plurality of pixels, and color signals determine RGB gray scales of pixels. In this embodiment, it is determined whether color signals of pixels are located in predetermined adjust regions of color space. If yes, an adjusting factor is determined based on the distance between the color signals and the boundary lines of adjust regions. The RGB gray scales of the color signals are adjusted based on the adjusting factor.

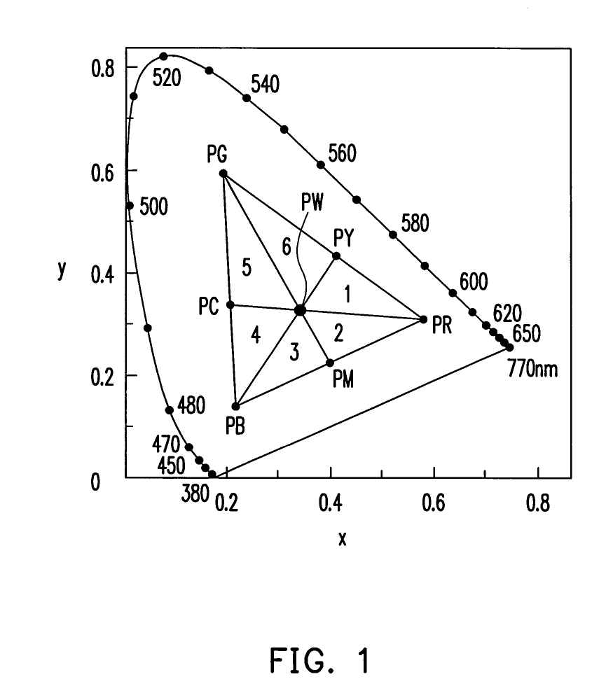

The adjust region is shown in FIG. 1, which shows a chromaticity diagram. In FIG. 1, the R, G and B signals in a display apparatus embodying the present invention are marked by the points PR, PG and PB. A triangle formed by these three points PR, PG and PB covers colors displayed on the display apparatus. The yellow, magenta and cyan signals are marked by the points PY, PM and PC on boundary lines of the triangle. The lines PR-PC, PG-PM and PB-PY divide the triangle into six color regions, labels by 1 to 6. The color regions 1˜6 have a common point PW, which indicates white signal. Table 1 defines the color regions 1˜6.

TABLE 1

| Color region | Constituting Points | Relationship between gray scales |
|---|---|---|
| 1 | PR, PY, PW | R > G > B |
| 2 | PR, PM, PW | R > B > G |
| 3 | PB, PM, PW | B > R > G |
| 4 | PB, PC, PW | B > G > R |
| 5 | PG, PC, PW | G > B > R |
| 6 | PG, PY, PW | G > R > B |

In this embodiment, the color region 1, including for example skin colors, is set as the adjust region. Of course, other color regions 2˜6 may be set as adjust regions, if necessary. In table 1, R, G and B represent the red, green and blue gray scales of color signals of a pixel. If R>G>B, the color signals are defined as being located in the adjust region. R>G>B is equivalent to both R>G and G>B. In FIG. 1, the color region 1 is bounded in the lines PY-PB (which means R=G) and PR-PC (which means G=B).

After the adjust region is determined, then, adjust factor are set. In this embodiment, the adjust factor is a product of two boundary factors Y_Gain and M_Gain (the adjust factor=Y_Gain*M_Gain). The boundary factor Y_Gain is related to the line PY-PB, and the boundary factor M_Gain is related to the line PR-PC. The boundary factor Y_Gain is defined as an ascending function of the distance between the color signal and the line PY-PB. Similarly, the boundary factor M_Gain is defined as an ascending function of the distance between the color signal and the line PR-PC. Tables 2 and 3 show the definition of Y_Gain and M_Gain.

TABLE 2

| R/G | Y_Gain |
|---|---|
| 1.00 ≦ R/G < 1.0625 | 0 |
| 1.0625 ≦ R/G < 1.1250 | 0.25 |
| 1.0625 ≦ R/G < 1.1875 | 0.5 |
| 1.1875 ≦ R/G < 1.25 | 0.75 |
| 1.25 ≦ R/G | 1 |

TABLE 3

| G/B | M_Gain |
|---|---|
| 1.00 ≦ G/B < 1.0625 | 0 |
| 1.0625 ≦ G/B < 1.1250 | 0.25 |
| 1.0625 ≦ G/B < 1.1875 | 0.5 |
| 1.1875 ≦ G/B < 1.25 | 0.75 |
| 1.25 ≦ G/B | 1 |

After the adjust factor is defined, the color signals are adjusted on the basis of the adjust factor. Rin, Gin and Bin are defined as original R, G and B gray scales of the input color signals and Rout, Gout and Bout are defined as the adjusted R, G and B gray scales. The adjusting formulae are as follows.
Rout=Rin+Y_Gain*M_Gain*R_Gain
Gout=Gin+Y_Gain*M_Gain*G_Gain
Bout=Bin+Y_Gain*M_Gain*B_Gain

(Y_Gain*M_Gain) is the adjust factor. R_Gin, G_Gain and B_Gain further control adjust degrees of R, G and B gray scales. R_Gin, G_Gain and B_Gain are either default or user-defined. Besides, R_Gin, G_Gain and B_Gain are either positive or negative, which means, in this embodiment, the gray scales may be increased or decreased. (Y_Gain*M_Gain*R_Gain), (Y_Gain*M_Gain*G_Gain) and (Y_Gain*M_Gain*B_Gain) are defined as gain factors. Of course, other adjusting formulae are suitable.
Rout=Rin*(1+Y_Gain*M_Gain*R_Gain)
Gout=Gin*(1+Y_Gain*M_Gain*G_Gain)
Bout=Bin*(1+Y_Gain*M_Gain*B_Gain)

Or, other formulae are applicable in the embodiment. For example, R_Gain, G_Gain and B_Gain are functions of Rin, Gin and Bin, in addition to default or user-defined. (1+Y_Gain*M_Gain*R_Gain), (1+Y_Gain*M_Gain*G_Gain) and (1+Y_Gain*M_Gain*B_Gain) are defined as gain factors.

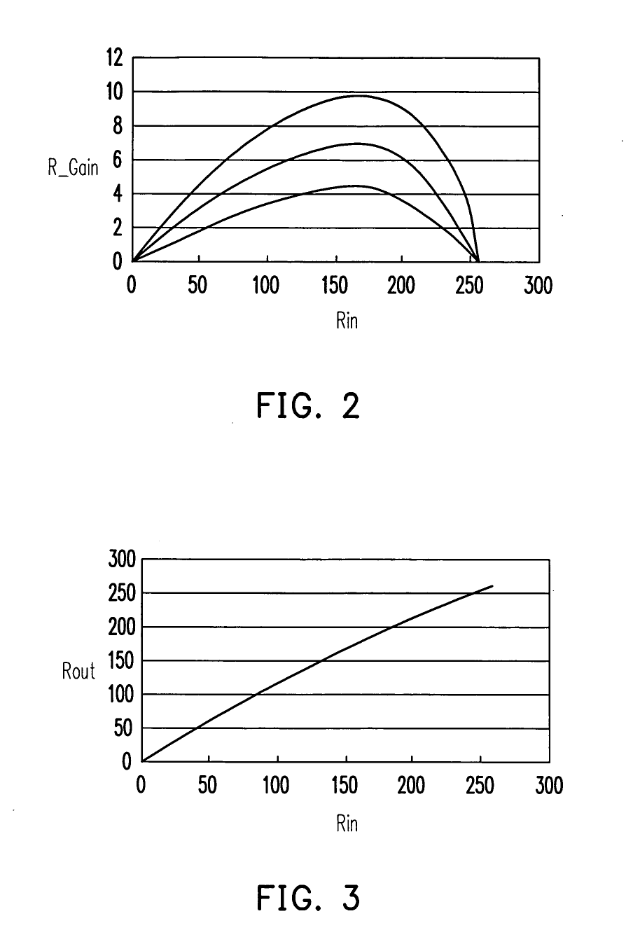

FIG. 2 shows the relationship between Rin and R_Gain. There are three curves in FIG. 2, and users may options one preferred. The curves indicate adjusted/gained gray scales preferable to human beings. Gray scales in the middle portion of the curves are related to large gains, and those on two ends of the curves are related to zero or small gains. The relationship between Rin and Rout is shown as FIG. 3 in the case applying the topmost Rin-R_Gain curve. It is noted that, the relationship line in FIG. 3 is not straight, but slightly protruded in its middle portion, to make human beings feel the difference between Rin and Rout. The invention is not limited by the curves in FIG. 2, and any acceptable curves are applicable.

As seen from the above tables 2 and 3, if the color signals locate on or close to the boundary lines of the adjust regions, the boundary factors Y_Gain and M_Gain are 0 or small. The farther the color signals away from the boundary lines of the adjust regions, the larger the boundary factors. The upper limit of the boundary factors is 1. The adjust effects of color signals locating on or close to the boundary lines are small, but the adjust effects of color signals far away from the boundary lines are significant. So the adjust effects are gradual, and the possibility of occurrence of error profiles is low. The definition of boundary factors are not limited by the ascending functions in tables 2 and 3. For example, there are more stages in defining the boundary factors, or the ascending functions are continuous, for smoother adjust effects.

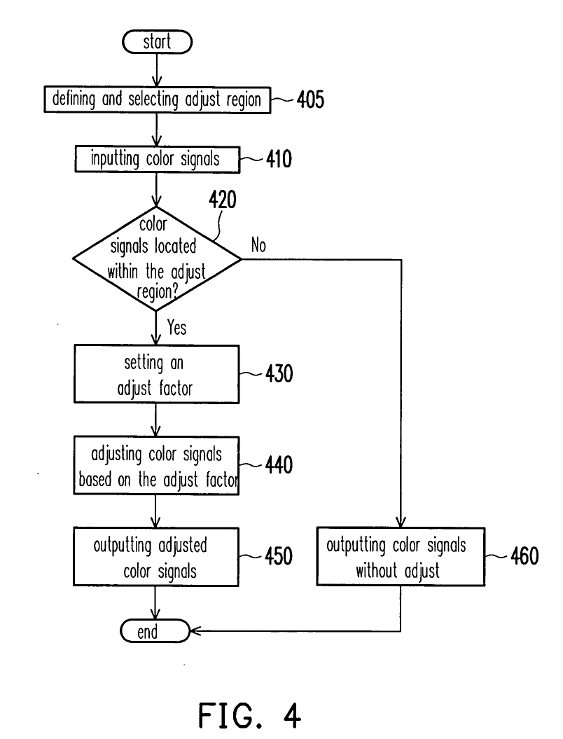

FIG. 4 shows a flow chart of the adjusting method for color images according to the embodiment of the invention. Adjust regions are defined and selected in step S405. Color signals are input, in step 410. It is determined whether the color signals are within the adjust regions, in step 420. If not, the color signals are output without adjust, in step 460.

If the color signals are within the adjust regions, the adjust factor is set based on the distance between the color signals and the boundaries of the adjust regions, in step 430. The R, G and B gray scales of the color signals are adjusted based on the adjust factor, in step 440. The adjusted color signals are output, in step 450.

The adjust regions may be in other shapes, for example polygon. Or, with definite definition, the adjust regions may be in curved shapes. Furthermore, distribution of the adjust region is not limited by the chromaticity diagram of FIG. 1. For example, the adjust regions is distributed in a three dimensional coordinate corresponding to RGB color model. With well-defined adjust factor, a good adjust effect is achieved.

The application of the invention is not limited in RGB color model. The invention is applicable in other color models, for example YMC (yellow, magenta, cyan) or HSV (hue, saturation, luminance) color models.

As described above, the adjusting method for color images according to the present invention adjusts color signals in predetermined regions under RGB color model, without conversion of color model. The complexity and cost of apparatus applying the invention is low. In the adjust method, the color images are adjusted based on the adjust factor, which is an ascending function of the distance between the color signals and the boundaries of the adjust regions. If the color signals locate on or close to the boundary lines of the adjust regions, the adjust factor are 0 or small, which means the adjust effects of color signals locating on or close to the boundary lines are small. On the other hand, the adjust effects of color signals far away from the boundary lines are significant. So the adjust effects are gradual for preventing occurrence of error profiles.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for adjusting color images, comprising the steps of:
defining and selecting an adjust region;
judging whether color signals of the color image are within the adjust region; and
adjusting gray scales of the color signals without conversion of color model, if the color signals are within the adjust region.

2. The method of claim 1, wherein the adjusting step further comprises the steps of:
defining an adjust factor based on a distance between the color signals and boundaries of the adjust region; and
adjusting red, green and blue gray scales of the color signals based on values of the adjust factor.

3. The method of claim 2, further comprising the steps of:
inputting the color signals; and
outputting the adjusted color signals.

4. The method of claim 3, further comprising the steps of:
outputting the color signals without adjust if the color signals are outside the adjust region.

5. The method of claim 2, wherein the boundaries of the adjust regions are defined by one or more inequalities including red, green and blue gray scales of the color signals.

6. The method of claim 5, wherein if the color signals satisfy R>G>B, the color signals are judged as being within the adjust regions, wherein R, G and B represent the red, green and blue gray scales of the color signals.

7. The method of claim 5, wherein the adjust factor is a product of a plurality of boundary factors, each corresponding to one of the inequalities.

8. The method of claim 7, wherein the boundary factor is defined based on a distance between the color signals and boundaries defined by the inequalities corresponding to the boundary factor.

9. The method of claim 8, wherein the boundary factor is an ascending function of the distance between the color signals and boundaries defined by the corresponding inequalities.

10. The method of claim 9, wherein the boundary factor is 0 if the color signals located on boundaries defined by the corresponding inequalities.

11. The method of claim 9, wherein an upper limit of the boundary factor is 1.

12. The method of claim 2, wherein the step of adjusting the color signals based on values of the adjust factor comprises the steps of:
adding corresponding gains to red, green and blue gray scales of the color signals, wherein the gains are determined based on the adjust factor.

13. The method of claim 2, wherein the step of adjusting the color signals based on values of the adjust factor comprises the steps of:
multiplying red, green and blue gray scales of the color signals by corresponding gains, wherein the gains are determined based on the adjust factor.

14. A method for adjusting color images, comprising the steps of:
defining and selecting an adjust region;
judging whether a color signal of the color image is located within the adjust region;
defining an adjust factor on the basis of a distance between the color signal and boundaries of the adjust region, if the color signal is located within the adjust region; and
adjusting the color signal based on values of the adjust factor without conversion of color model.

15. The method of claim 14, wherein the boundaries of the adjust regions are defined by one or more inequalities.

16. The method of claim 15, wherein the adjust factor is a product of a plurality of boundary factors, each corresponding to one of the inequalities.

17. The method of claim 16, wherein the boundary factor is defined based on a distance between the color signals and the boundaries defined by the corresponding inequalities of the boundary factor.

18. The method of claim 17, wherein the boundary factor is an ascending function of the distance between the color signals and the boundaries defined by the corresponding inequalities of the boundary factor.

19. The method of claim 18, wherein the boundary factor is 0 if the color signals located on the corresponding boundaries defined by the inequalities.

20. The method of claim 18, wherein an upper limit of the boundary factor is 1.
